(19) United States
(12) Patent Application Publication
(10) Pub. No.: US 2002/0053739 A1
(43) Pub. Date: May 9, 2002

(54) Semiconductor device and method of fabricating the same

(75) Inventors: Kazunari Honma, Ogaki-shi (JP); Shigeharu Matsushita, Osaka (JP)

Correspondence Address: ARENT FOX KINTNER PLOTKIN & KAHN, PLLC, 1050 Connecticut Avenue, N.W., Suite 400, Washington, DC, 20036-5339, US

(73) Assignee: SANYO ELECTRIC CO., LTD.

(21) Appl. No.: 09/951,508

(22) Filed: Sep. 14, 2001

(30) Foreign Application Priority Data
Nov. 7, 2000 (JP) JP2000-338697

(51) Int. Cl. H01L 23/48; H01L 23/52; H01L 29/40

(52) U.S. Cl. 257/758

(57) ABSTRACT

A semiconductor device capable of implementing a multilevel interconnection structure employing a tungsten plug after formation of a capacitor element including an oxide-based dielectric film by suppressing downward diffusion of hydrogen is obtained. This semiconductor device comprises a first interlayer dielectric film having a first opening, a first barrier film, formed at least along the inner side surface of the first opening, having a function of preventing diffusion of hydrogen, and a first conductive material embedded in the first opening through the first barrier film. Thus, the first barrier film functions as a barrier film preventing diffusion of hydrogen. Also when the tungsten plug is formed after formation of the capacitor element including the oxide-based dielectric film, therefore, the first barrier film can prevent hydrogen from diffusing into the oxide-based dielectric film.

### BACKGROUND OF THE INVENTION

1. Field of the Invention

The present invention relates to a semiconductor device and a method of fabricating the same, and more specifically, it relates to a semiconductor device including a capacitor element having an oxide-based dielectric film and a method of fabricating the same.

2. Description of the Prior Art

A ferroelectric memory is recently energetically studied as a high-speed nonvolatile memory having low power consumption. FIG. 10 is a sectional view showing the structure of a conventional semiconductor device including a ferroelectric memory.

The structure of the conventional semiconductor device including a ferroelectric memory is now described with reference to FIG. 10. In this conventional semiconductor device, an element isolation film 102 is formed on the surface of a p-type silicon substrate 101. Diffusion layers 107 for defining source/drain regions of transistors are formed on an active region enclosed with the element isolation film 102 at prescribed distances. Gate electrodes of a polycide structure consisting of multilayer films of polysilicon films 104 and WSi films 105 are formed on channel regions located between the diffusion layers 107 through gate oxide films 103. Side wall insulator films 106 are formed on the side walls of the gate electrodes.

An interlayer dielectric film 108 is formed to cover the overall surface. Contact holes 108a are formed in regions of the interlayer dielectric film 108 located on the diffusion layers 107. Barrier films 109 consisting of multilayer films (TiN/Ti films) including TiN films and Ti films are formed in the contact holes 108a. The barrier films 109 consisting of the TiN/Ti films are provided for preventing Si forming the p-type silicon substrate 101 and W forming tungsten plugs 110 from reacting with each other. The tungsten plugs 110 are embedded in the barrier films 109. Lower electrodes 111 of ferroelectric capacitors and a pad layer 111a are formed on the tungsten plugs 110.

An interlayer dielectric film 112 is formed to cover the lower electrodes 111 and the pad layer 111a. Openings 112a are formed in regions of the interlayer dielectric film 112 located on the lower electrodes 111. SrBi₂Ta₂O₉ (SBT) films 113 which are ferroelectric films are formed to fill up the openings 112a. Pt films 114 which are upper electrodes are formed on the SBT films 113. An interlayer dielectric film 115 is formed to cover the Pt films 114. Via holes 115a and 112b reaching the pad layer 111a are formed in the central portions of the interlayer dielectric films 115 and 112 respectively. A barrier film 118 consisting of TiN/Ti is formed along the inner side surfaces of the via holes 112b and 115a and the upper surface of the interlayer dielectric film 115. A metal wiring layer 119 is formed on the barrier film 118.

In the aforementioned conventional semiconductor device including a ferroelectric memory element, however, it is difficult to connect the metal wiring layer 119 formed after formation of ferroelectric capacitor elements including the SBT films 113 which are ferroelectric films with the lower pad layer 111a by embedding a tungsten plug for the following reason:

In order to form a tungsten plug, H₂ (hydrogen) is employed as a reductant for removing F from WF₆ in deposition of tungsten (W). When this hydrogen employed for forming the tungsten plug diffuses into the ferroelectric films (SBT films 113) of the ferroelectric capacitor elements, the remanence values of the ferroelectric films abruptly deteriorate to exhibit no memory holdability. The generally employed barrier film 118 consisting of TiN/Ti cannot prevent diffusion of hydrogen employed for forming the tungsten plug. In a metal wiring process after formation of the ferroelectric capacitor elements, therefore, it is difficult to embed the tungsten plug. In the conventional semiconductor device shown in FIG. 10, therefore, no tungsten plug is embedded in the via holes 115a and 112b formed after formation of the ferroelectric capacitor elements but the metal wiring layer 119 is directly formed.

Thus, the single metal wiring layer 119 is generally employed as a wiring layer after formation of the ferroelectric capacitor elements, and it is difficult to apply a multilevel interconnection technique employing a tungsten plug.

When no technique of embedding a tungsten plug can be employed as described above, the diameters of the via holes 115a and 112b are disadvantageously inevitably increased. A tungsten plug (tungsten layer) formed by CVD can be embedded in the via holes 115a and 112b also when the via holes 115a and 112b have small diameters. On the other hand, the metal wiring layer 119 formed on the side wall portion of the via hole 112b by sputtering is reduced in thickness when the via holes 115a and 112b have small diameters. In order to form the metal wiring layer 119 in the via holes 115a and 112b by sputtering, therefore, the diameters of the via holes 115a and 112b must be increased. When the diameters of the via holes 115a and 112b are increased, however, it is difficult to refine the ferroelectric memory device.

When formed in the via holes 115a and 112b, the metal wiring layer 119 is not completely embedded in the via holes 115a and 112b and hence the upper surface thereof is concaved as shown in FIG. 10. In this case, it is difficult to form an upper via hole (not shown) immediately above the via hole 115a. Therefore, the upper via hole must be provided on a position displaced from the lower via hole 115a. When the upper via hole is provided on such a displaced position, however, refinement of the ferroelectric memory device is hindered also when the multilevel interconnection structure is employed.

As hereinabove described, it is difficult to effectively prevent diffusion of hydrogen employed for depositing a conductive material such as a tungsten plug in general. Therefore, it is difficult to employ a tungsten plug after formation of a ferroelectric capacitor. Thus, it is difficult to refine a ferroelectric memory device. Further, it is difficult to combine the hardly refined ferroelectric memory device with a logic LSI.

### SUMMARY OF THE INVENTION

An object of the present invention is to provide a semiconductor device capable of effectively preventing diffusion of hydrogen employed when depositing a conductive material such as a tungsten plug.

Another object of the present invention is to provide a semiconductor device capable of forming a multilevel interconnection structure employing a tungsten plug after formation of a capacitor element including an oxide-based dielectric film without deteriorating the characteristics of the oxide-based dielectric film.

Still another object of the present invention is to provide a method of fabricating a semiconductor device capable of readily forming a multilevel interconnection structure employing a tungsten plug after formation of a capacitor element including an oxide-based dielectric film without deteriorating the characteristics of the oxide-based dielectric film.

A semiconductor device according to a first aspect of the present invention comprises a first interlayer dielectric film having a first opening, a first barrier film, formed at least along the inner side surface of the first opening, having a function of preventing diffusion of hydrogen, and a first conductive material embedded in the first opening through the first barrier film.

In the semiconductor device according to the first aspect, the first barrier film functions as a barrier film preventing diffusion of hydrogen due to the aforementioned structure. Thus, when a tungsten plug is employed as the first conductive material, for example, the first barrier film can prevent downward diffusion of hydrogen (H₂) employed for forming the tungsten plug. Also when the tungsten plug is formed after formation of a capacitor element including an oxide-based dielectric film, therefore, hydrogen can be prevented from diffusing into the oxide-based dielectric film and deteriorating the characteristics of the oxide-based dielectric film. Therefore, a multilevel interconnection structure employing the tungsten plug can be implemented after formation of the capacitor element including the oxide-based dielectric film. Consequently, the semiconductor device having the capacitor element including the oxide-based dielectric film can be refined.

In the semiconductor device according to the aforementioned first aspect, the first barrier film preferably contains a metal including at least one element selected from a group consisting of Ir, Pt, Ru, Re, Ni, Co and Mo, silicon and nitrogen. Thus, the first barrier film can function as a barrier film preventing diffusion of hydrogen. In this case, the first barrier film preferably includes either an IrSiN film or a PtSiN film.

In the semiconductor device according to the aforementioned first aspect, the first conductive material preferably includes a tungsten plug. Thus, a conventional technique of forming a tungsten plug can be applied to the multilevel interconnection structure as such with no problem.

The semiconductor device according to the aforementioned first aspect preferably further comprises a capacitor element including an oxide-based dielectric film, and the first barrier film and the first conductive material are preferably formed after formation of at least the capacitor element including the oxide-based dielectric film. Thus, also when a tungsten plug is employed as the first conductive material, the first barrier film prevents hydrogen employed for forming the tungsten plug from diffusing into the capacitor element including the oxide-based dielectric film. Consequently, a multilevel interconnection structure employing the tungsten plug can be readily formed after formation of the capacitor element including the oxide-based dielectric film. In this case, the capacitor element may include a ferroelectric capacitor having a ferroelectric film.

In the aforementioned semiconductor device, the first barrier film and the first conductive material are preferably formed not only after formation of the capacitor element including the oxide-based dielectric film but also before formation of the capacitor element including the oxide-based dielectric film. Thus, the first barrier film can prevent diffusion of hydrogen employed for forming the tungsten plug also before formation of the capacitor element. Thus, such diffusing hydrogen can be effectively prevented from deteriorating the characteristics of the subsequently formed ferroelectric capacitor.

The semiconductor device according to the aforementioned first aspect preferably further comprises a first metal wiring layer formed on the first conductive material, a second insulator film, formed on the first metal wiring layer, having a second opening reaching the first metal wiring layer, a second barrier film, formed at least along the inner side surface of the second opening, having a function of preventing diffusion of hydrogen, a second conductive material embedded in the second opening through the second barrier film, and a second metal wiring layer formed on the second conductive material. Thus, when a tungsten plug is employed as the second conductive material, a multilevel interconnection layer consisting of the first and second metal wiring layers employing the tungsten plug can be readily formed. In this case, the second barrier film prevents diffusion of hydrogen employed for forming the tungsten plug as the second conductive material, whereby the multilevel interconnection structure employing the tungsten plug can be formed with no problem after formation of the capacitor element including the oxide-based dielectric film.

This semiconductor device preferably further comprises a third barrier film, formed between the second conductive material and the second metal wiring layer, for preventing the second conductive material and the second metal wiring layer from reacting with each other. Thus, the third barrier layer can readily prevent the second conductive material and the second metal wiring layer from reacting with each other.

In this semiconductor device, the second barrier film preferably contains a metal including at least one element selected from a group consisting of Ir, Pt, Ru, Re, Ni, Co and Mo, silicon and nitrogen. Thus, the second barrier film can function as a barrier film preventing diffusion of hydrogen. In this case, the second barrier film may include either an IrSiN film or a PtSiN film.

In this semiconductor device, the second conductive material preferably includes a tungsten plug. Thus, the conventional technique of forming a tungsten plug can be applied to the multilevel interconnection structure as such with no problem.

A method of fabricating a semiconductor device according to a second aspect of the present invention comprises steps of forming a capacitor element including an oxide-based dielectric film, forming a first interlayer dielectric film having a first opening after formation of the capacitor element, forming a first barrier film having a function of preventing diffusion of hydrogen to cover the inner side surface of the first opening and the upper surface of the first interlayer dielectric film, forming a first conductive material to fill up the first opening through the first barrier film and extend onto the first barrier film located on the first interlayer dielectric film and removing parts of the first conductive material and the first barrier film located on the first interlayer dielectric film thereby leaving the first conductive material only in the first opening.

In the method of fabricating a semiconductor device according to the second aspect, the first barrier film functions as a barrier film preventing diffusion of hydrogen due to the aforementioned structure. Thus, when a tungsten plug is employed as the first conductive material, for example, the first barrier film can prevent downward diffusion of hydrogen (H₂) employed for forming the tungsten plug. In other words, the first barrier film, formed to cover the overall surfaces of the first opening and the first interlayer dielectric film in formation of the first conductive material, can block downward diffusion of hydrogen. Also when the tungsten plug is formed after formation of a capacitor element including an oxide-based dielectric film, therefore, hydrogen can be prevented from diffusing into the oxide-based dielectric film and deteriorating the characteristics of the oxide-based dielectric film. Therefore, the tungsten plug can be formed after formation of the capacitor element including the oxide-based dielectric film, whereby a multilevel interconnection structure employing the tungsten plug can be readily formed.

In the method of fabricating a semiconductor device according to the aforementioned second aspect, the first barrier film preferably contains a metal including at least one element selected from a group consisting of Ir, Pt, Ru, Re, Ni, Co and Mo, silicon and nitrogen. Thus, the first barrier film can function as a barrier film preventing diffusion of hydrogen. In this case, the first barrier film preferably includes either an IrSiN film or a PtSiN film.

In the method of fabricating a semiconductor device according to the aforementioned second aspect, the first conductive material preferably includes a tungsten plug. Thus, the conventional technique of forming a tungsten plug can be applied to the multilevel interconnection structure as such with no problem.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a semiconductor device including a ferroelectric capacitor element according to a first embodiment of the present invention;

FIGS. 2 to 7 are sectional views for illustrating a process of fabricating the semiconductor device according to the first embodiment shown in FIG. 1;

FIG. 8 is a sectional view showing a semiconductor device according to a modification of the first embodiment shown in FIG. 1;

FIG. 9 is a sectional view showing a semiconductor device including a ferroelectric memory according to a second embodiment of the present invention; and

FIG. 10 is a sectional view showing a conventional semiconductor device including a ferroelectric memory.

### DESCRIPTION OF THE PREFERRED EMBODIMENTS

Embodiments of the present invention are now described with reference to the drawings.

(First Embodiment)

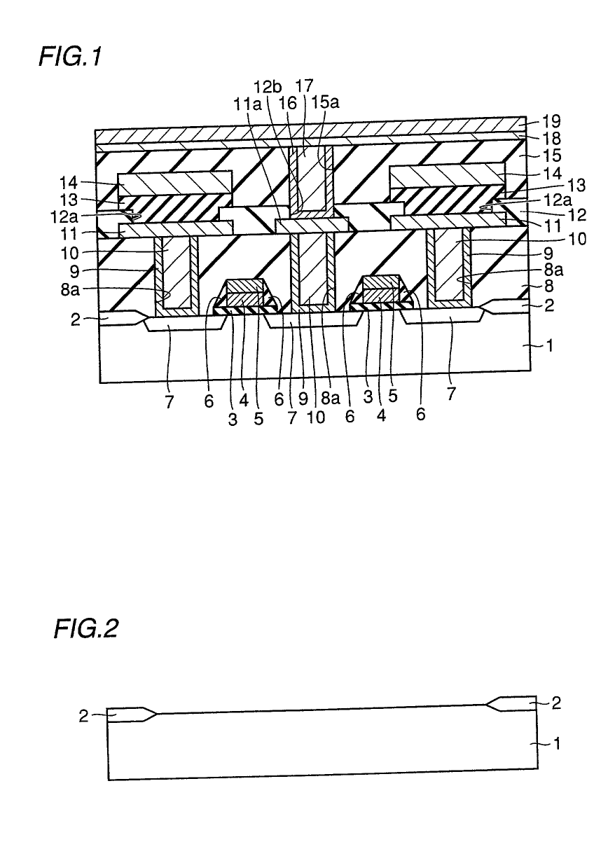

Referring to FIG. 1, the structure of a semiconductor device according to a first embodiment of the present invention is now described. According to the first embodiment, an element isolation film 2 is formed on a prescribed region of the surface of a p-type silicon substrate 1. The element isolation film 2 separates the surface of the p-type silicon substrate 1 into an active region and a field region (element isolation region). Diffusion layers 7 for defining source/drain regions are formed on the active region at prescribed distances. Gate oxide films 3 consisting of SiO₂ are formed in a thickness of about 5 nm on channel regions located between the diffusion layers 7. Gate electrodes of a polycide structure consisting of multilayer films of polysilicon films 4 and WSi films 5 located thereon are formed on the gate oxide films 3. Side wall insulator films 6 consisting of silicon oxide are formed on both side surfaces of the gate electrodes.

An interlayer dielectric film 8 consisting of silicon oxide is formed to cover the overall surface. Contact holes 8a are formed in regions of the interlayer dielectric film 8 located on the diffusion layers 7. Barrier films 9 consisting of TiN/Ti are formed in the contact holes 8a. Lower Ti films forming the barrier films 9 are 5 nm to 15 nm in thickness, and upper TiN films are 20 nm to 40 nm in thickness. Tungsten plugs 10 are embedded in regions enclosed with the barrier films 9. The barrier films 9 consisting of TiN/Ti have a function of preventing silicon (Si) forming the p-type silicon substrate 1 and tungsten (W) forming the tungsten plugs 10 from reacting with each other.

IrSiN films 11 and 11a are formed on the tungsten plugs 10. The IrSiN films 11 define lower electrodes of ferroelectric capacitors. The IrSiN film 11a defines a pad layer. An interlayer dielectric film 12 consisting of silicon nitride or silicon oxide is formed to cover the IrSiN films 11 and 11a. Openings 12a deciding the areas of the ferroelectric capacitors and a via hole 12b are formed in the interlayer dielectric film 12. SBT films 13 which are ferroelectric films are formed in the openings 12a and on parts of the interlayer dielectric film 12. Pt films 14 for defining upper electrodes are formed on the SBT films 13.

An interlayer dielectric film 15 consisting of silicon oxide is formed to cover the Pt films 14. A via hole 15a communicating with the via hole 12b is formed in the interlayer dielectric film 15. A barrier film 16 consisting of IrSiN having a thickness of 30 nm to 50 nm is formed in the via holes 12b and 15a. The barrier film 16 consisting of IrSiN has a function of preventing diffusion of hydrogen.

A tungsten plug 17 is embedded in a region enclosed with the barrier film 16 consisting of IrSiN. The barrier film 16 consisting of IrSiN is an example of the “first barrier film” according to the present invention, and the tungsten plug 17 is an example of the “first conductive material” according to the present invention. A barrier film 18 consisting of TiN/Ti is formed to extend along the tungsten plug 17 and the interlayer dielectric film 15. A lower Ti film forming the barrier film 18 has a thickness of 5 nm to 15 nm, and an upper TiN film has a thickness of 20 nm to 40 nm. A metal wiring layer 19 consisting of Al—Si—Cu is formed on the barrier film 18. The barrier film 18 consisting of TiN/Ti has a function of preventing the metal wiring layer 19 consisting of Al—Si—Cu and the tungsten plug 17 from reacting with each other. The barrier film 18 is an example of the “third barrier film” according to the present invention.

According to the first embodiment, the tungsten plug 17 is formed after forming the barrier film 16 of IrSiN having a hydrogen diffusion preventing function in the via holes 12b and 15a formed after formation of the ferroelectric capacitors consisting of the IrSiN films 11, the SBT films 13 and the Pt films 14, whereby hydrogen (H₂) employed for forming the tungsten plug 17 can be effectively prevented from diffusing into the SBT films 13 of the ferroelectric capacitors in a fabrication process described later.

Also when the tungsten plug 17 is formed after formation of the ferroelectric capacitors, therefore, the SBT films 13 can be prevented from deterioration of characteristics. Consequently, the tungsten plug 17 can be readily formed after formation of the ferroelectric capacitors including the SBT films 13. Thus, a multilevel interconnection structure employing the tungsten plug 17 can be implemented after formation of the ferroelectric capacitors including the SBT films 13, so that the ferroelectric memory device can be refined as a result. Thus, the ferroelectric memory device can be combined with a logic LSI.

The fabrication process for the semiconductor device according to the first embodiment is now described with reference to FIGS. 2 to 7.

First, the element isolation film 2 is formed on the surface of the p-type silicon substrate 1 by a LOCOS (local oxidation of silicon) method, as shown in FIG. 2. Thus, the p-type silicon substrate 1 is separated into the active region and the field region (element isolation region).

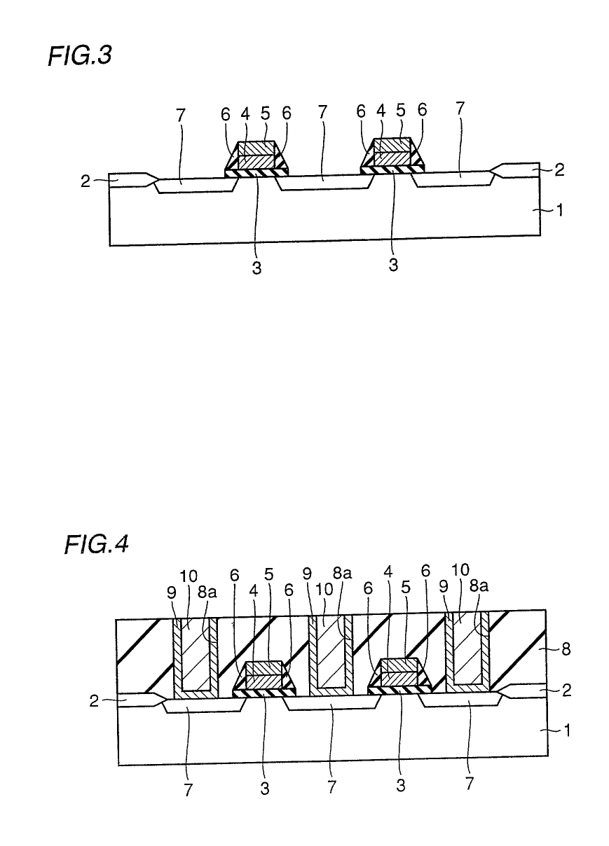

Then, an impurity for adjusting the threshold voltage of a transistor is ion-implanted into the active region, as shown in FIG. 3. For example, boron is implanted under conditions of 20 keV and 5E12 cm⁻² for an n-channel transistor. Thereafter the gate oxide films 3 consisting of SiO₂ are formed on the p-type silicon substrate 1 in a thickness of about 5 nm. The polysilicon films 4 and the WSi films 5 are successively deposited on the gate oxide films 3, and thereafter patterned into prescribed shapes through photolithography and dry etching.

A silicon oxide film (not shown) is deposited on the overall surface and thereafter anisotropically etched thereby forming the side wall insulator films 6 on the side walls of the gate electrodes having a polycide structure formed by the polysilicon films 4 and the WSi films 5. An impurity is ion-implanted into the p-type silicon substrate 1 through the side wall insulator films 6 and the WSi films 5 serving as masks, thereby forming the diffusion layers 7 for defining source/drain regions. For example, arsenic is implanted under conditions of 30 keV and 2E15 cm⁻² for the n-channel transistor.

Then, the interlayer dielectric film 8 consisting of silicon oxide is deposited to cover the overall surface and the contact holes 8a are thereafter formed in the interlayer dielectric film 8 through photolithography and dry etching, as shown in FIG. 4. The barrier films 9 consisting of TiN/Ti are deposited on the inner side surfaces of the contact holes 8a and the upper surface of the interlayer dielectric film 8. Thereafter tungsten layers (not shown) for forming the tungsten plugs 10 are deposited on the barrier films 9. The tungsten layers and the barrier films 9 deposited on the interlayer dielectric film 8 are partially removed by etching or CMP, thereby leaving the barrier films 9 consisting of TiN/Ti and the tungsten plugs 10 only in the contact holes 8a.

Then, an IrSiN film is deposited and thereafter patterned thereby forming the IrSiN films 11 for defining the lower electrodes and the IrSiN film 11a for defining the pad layer, as shown in FIG. 5. The interlayer dielectric film 12 consisting of silicon oxide or silicon nitride is formed to cover the IrSiN films 11 and 11a. The openings 12a deciding the areas of the ferroelectric capacitors are formed through photolithography and dry etching. Thereafter the SBT films 13 which are ferroelectric films are deposited in the openings 12a and on the interlayer dielectric film 12 by a sol-gel method. Then, the Pt films 14 for defining the upper electrodes are deposited.

The Pt films 14 and the SBT films 13 are patterned into prescribed shapes by photolithography and dry etching. Thereafter annealing is performed in an oxygen atmosphere at a high temperature (600° C. to 800° C.) for about 30 minutes, in order to recover defects caused in the etching step for patterning the Pt films 14 and the SBT films 13 thereby improving the characteristics of the ferroelectric capacitors.

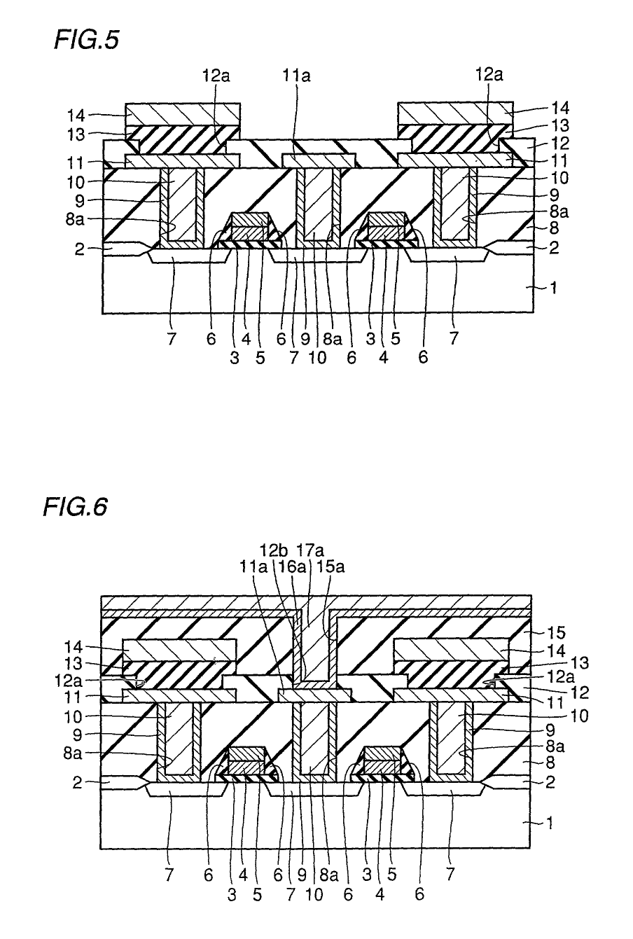

Then, the interlayer dielectric film 15 of silicon oxide is deposited to cover the overall surface, as shown in FIG. 6. The via holes 15a and 12b reaching the IrSiN film 11a are formed in the interlayer dielectric film 15 by photolithography and dry etching. A barrier film layer 16a consisting of IrSiN is deposited by sputtering or CVD, to extend on the inner side surfaces of the via holes 12b and 15a and the upper surface of the interlayer dielectric film 15. A tungsten layer 17a for embedding is deposited on the barrier film layer 16a by CVD. In this case, the barrier film layer 16a is formed to cover the overall surface, and hence hydrogen employed for depositing the tungsten layer 17a is effectively prevented from downward diffusion.

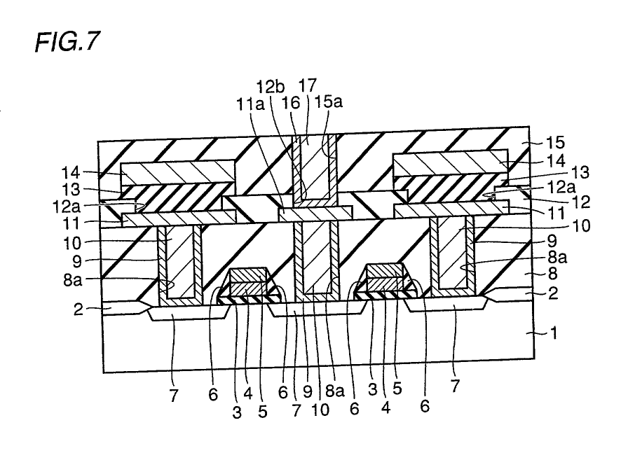

The tungsten layer 17a and the barrier film layer 16a deposited on the interlayer dielectric film 15 are removed by etching or CMP. Thus, the barrier film 16 and the tungsten plug 17 embedded in the via holes 12b and 15a are formed as shown in FIG. 7.

Thereafter the TiN/Ti film 18 is formed to extend along the tungsten plug 17 and the interlayer dielectric film 15 and the metal wiring layer 19 consisting of Al—Si—Cu is formed on the TiN/Ti film 18, as shown in FIG. 1. Then, the metal wiring layer 19 and the TiN/Ti film 18 are patterned into prescribed shapes by photolithography and dry etching.

Thus, the semiconductor device including a ferroelectric memory according to the first embodiment is fabricated as shown in FIG. 1.

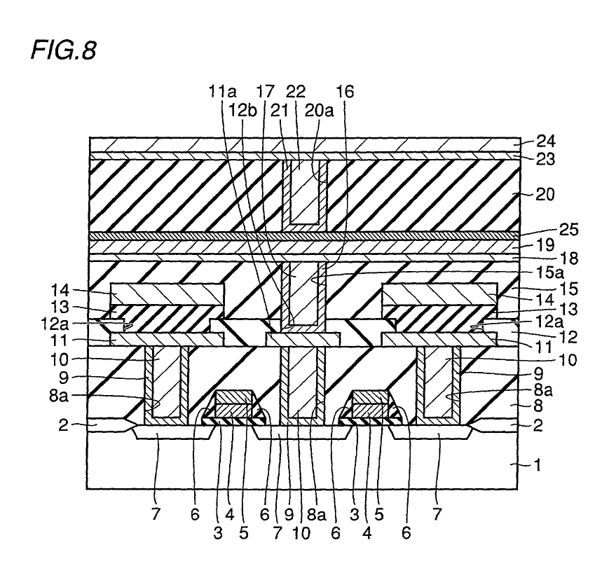

FIG. 8 is a sectional view showing a modification of the semiconductor device according to the first embodiment shown in FIG. 1. Referring to FIG. 8, the modification of the first embodiment has a multilevel interconnection structure formed by further arranging a metal wiring layer 24 above the metal wiring layer 19 in the structure of the first embodiment shown in FIG. 1.

In the modification of the first embodiment, an interlayer dielectric film 20 is formed on the metal wiring layer 19 through a Ti layer 25 having a thickness of 200 nm to 400 nm. A via hole 20a reaching the Ti layer 25 is formed in the interlayer dielectric film 20. A barrier film 21 consisting of IrSiN having a function of preventing diffusion of hydrogen is formed in the via hole 20a. A tungsten plug 22 is formed in a region enclosed with the barrier film 21. A TiN/Ti film 23 is formed on the tungsten plug 22 and the interlayer dielectric film 20. The upper metal wiring layer 24 consisting of Al—Si—Cu is formed on the TiN/Ti film 23.

Thus, the barrier film 21 consisting of IrSiN having a function of preventing diffusion of hydrogen can inhibit hydrogen employed for forming the tungsten plug 22 from diffusing into SBT films 13. Also when the tungsten plug 22 is employed in the multilevel interconnection structure after formation of ferroelectric capacitors, therefore, the characteristics of the ferroelectric capacitors are not deteriorated. According to this modification, therefore, the multilevel interconnection structure can be formed by the lower metal wiring layer 19 and the upper metal wiring layer 24 with the tungsten plug 22.

The lower metal wiring layer 19 is an example of the “first metal wiring layer” according to the present invention, and the upper metal wiring layer 24 is an example of the “second metal wiring layer” according to the present invention. Further, the barrier film 21 consisting of IrSiN is an example of the “second barrier film” according to the present invention, and the tungsten plug 22 is an example of the “second conductive material” according to the present invention.

While the modification of the first embodiment shown in FIG. 8 is formed by two metal wiring layers, the present invention is not restricted to this but a multilevel interconnection structure having three or more layers can be similarly implemented with a tungsten plug.

In order to fabricate the modification of the first embodiment shown in FIG. 8, the Ti layer 25 is formed after formation of the metal wiring layer 19. The interlayer dielectric film 20 consisting of silicon oxide is deposited on the Ti layer 25. The via hole 20a is opened in the interlayer dielectric film 20. An IrSiN film and a tungsten layer are deposited in the via hole 20a and on the interlayer dielectric film 20, and parts of the IrSiN film and the tungsten layer deposited on the interlayer dielectric film 20 are removed by etching or CMP. Thus, the barrier film 21 consisting of IrSiN and the tungsten plug 22 embedded in the via hole 20a are formed. Thereafter the TIN/Ti film 23 and the metal wiring layer 24 consisting of Al—Si—Cu are deposited and thereafter patterned into prescribed shapes. Thus, the structure of the modification of the first embodiment is completed as shown in FIG. 8.

When repeating the aforementioned fabrication process according to the modification of the first embodiment, it is also possible to form a multilevel interconnection structure having three or more layers.

(Second Embodiment)

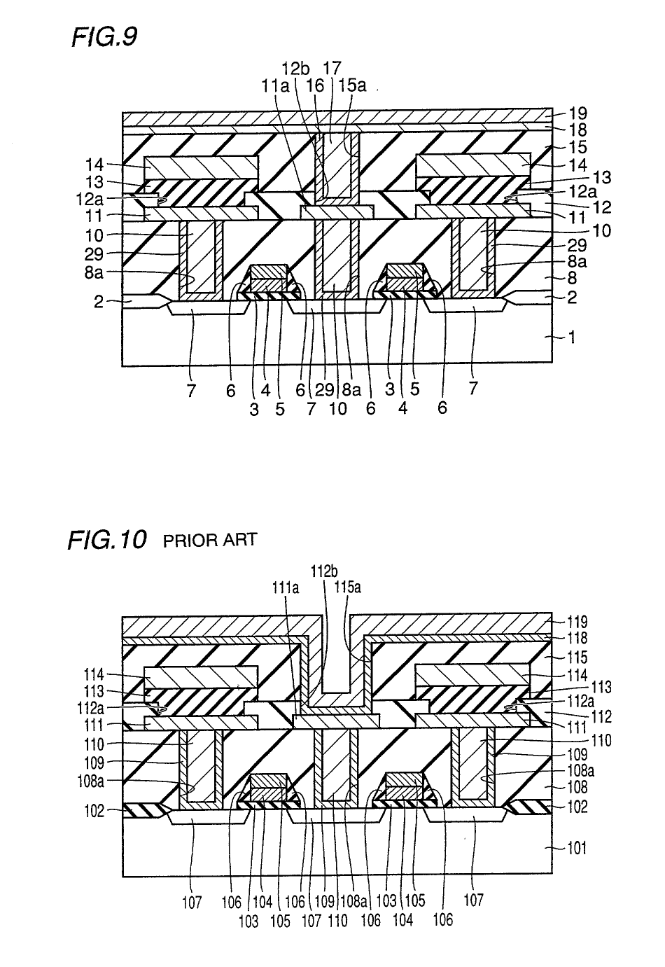

Referring to FIG. 9, a semiconductor device according to a second embodiment of the present invention is basically identical in structure to the first embodiment shown in FIG. 1. According to the second embodiment, however, barrier films 29 formed in contact holes 8a of an interlayer dielectric film 8 located under ferroelectric capacitors are formed by IrSiN films having a function of preventing diffusion of hydrogen, dissimilarly to the aforementioned first embodiment. The barrier films 29 consisting of IrSiN are examples of the “first barrier film” according to the present invention. In this case, tungsten plugs 10 are examples of the “first conductive material” according to the present invention.

According to the second embodiment, the barrier films 29 of IrSiN having a function of preventing diffusion of hydrogen are formed in the contact holes 8a located under the ferroelectric capacitors, so that diffusion of hydrogen employed for forming the tungsten plugs 10 can be prevented. Thus, such diffusing hydrogen can be effectively prevented from deteriorating the characteristics of the subsequently formed ferroelectric capacitors.

A fabrication process for the semiconductor device according to the second embodiment is basically similar to the aforementioned fabrication process according to the first embodiment, and hence redundant description is not repeated. The fabrication process according to the second embodiment is different from the fabrication process according to the first embodiment only in a point that the barrier films 29 consisting of IrSiN are formed in place of the barrier films 9 consisting of TiN/Ti in a step similar to that shown in FIG. 4.

Although the present invention has been described and illustrated in detail, it is clearly understood that the same is by way of illustration and example only and is not to be taken by way of limitation, the spirit and scope of the present invention being limited only by the terms of the appended claims.

For example, while the SBT films 13 which are ferroelectric films are employed as oxide-based dielectric films in each of the aforementioned embodiments, the present invention is not restricted to this but other oxide-based ferroelectric films such as PbZrₓTi₁₋ₓO₃ (PZT) films, for example, may alternatively be employed.

While IrSiN films are employed as the barrier films 16, 21 and 29 preventing diffusion of hydrogen employed for forming the tungsten plugs in the aforementioned embodiments, the present invention is not restricted to this but PtSiN films may alternatively be employed. Further alternatively, films consisting of metal (M)—Si—N may be employed. An effect similar to the above can be attained also when Ru, Re, Ni, Co or Mo is employed as the metal (M) in the above composition in place of Ir or Pt. Further, films of these metals may be combined with each other.

While the Ti layer 25 is formed on the metal wiring layer 19 in the aforementioned modification of the first embodiment, the present invention is not restricted to this but a TiN layer or a TiN/Ti layer may alternatively be formed in place of the TiN layer 25.

While the present invention is applied to a semiconductor device including capacitor elements having oxide-based dielectric films in each of the aforementioned first and second embodiments, the present invention is not restricted to this but applicable to a general structure employing a plug.

What is claimed is:

1. A semiconductor device comprising:
a first interlayer dielectric film having a first opening;
a first barrier film, formed at least along the inner side surface of said first opening, having a function of preventing diffusion of hydrogen; and
a first conductive material embedded in said first opening through said first barrier film.

2. The semiconductor device according to claim 1, wherein
said first barrier film contains a metal including at least one element selected from a group consisting of Ir, Pt, Ru, Re, Ni, Co and Mo, silicon and nitrogen.

3. The semiconductor device according to claim 2, wherein
said first barrier film includes either an IrSiN film or a PtSiN film.

4. The semiconductor device according to claim 1, wherein
said first conductive material includes a tungsten plug.

5. The semiconductor device according to claim 1, further comprising a capacitor element including an oxide-based dielectric film, wherein
said first barrier film and said first conductive material are formed after formation of at least said capacitor element including said oxide-based dielectric film.

6. The semiconductor device according to claim 5, wherein
said capacitor element includes a ferroelectric capacitor having a ferroelectric film.

7. The semiconductor device according to claim 5, wherein
said first barrier film and said first conductive material are formed not only after formation of said capacitor element including said oxide-based dielectric film but also before formation of said capacitor element including said oxide-based dielectric film.

8. The semiconductor device according to claim 1, further comprising:
a first metal wiring layer formed on said first conductive material,
a second insulator film, formed on said first metal wiring layer, having a second opening reaching said first metal wiring layer,
a second barrier film, formed at least along the inner side surface of said second opening, having a function of preventing diffusion of hydrogen,
a second conductive material embedded in said second opening through said second barrier film, and
a second metal wiring layer formed on said second conductive material.

9. The semiconductor device according to claim 8, further comprising a third barrier film, formed between said second conductive material and said second metal wiring layer, for preventing said second conductive material and said second metal wiring layer from reacting with each other.

10. The semiconductor device according to claim 8, wherein
said second barrier film contains a metal including at least one element selected from a group consisting of Ir, Pt, Ru, Re, Ni, Co and Mo, silicon and nitrogen.

11. The semiconductor device according to claim 10, wherein
said second barrier film includes either an IrSiN film or a PtSiN film.

12. The semiconductor device according to claim 8, wherein
said second conductive material includes a tungsten plug.

13. A method of fabricating a semiconductor device comprising steps of:
forming a capacitor element including an oxide-based dielectric film;
forming a first interlayer dielectric film having a first opening after formation of said capacitor element;
forming a first barrier film having a function of preventing diffusion of hydrogen to cover the inner side surface of said first opening and the upper surface of said first interlayer dielectric film;
forming a first conductive material to fill up said first opening through said first barrier film and extend onto said first barrier film located on said first interlayer dielectric film; and
removing parts of said first conductive material and said first barrier film located on said first interlayer dielectric film thereby leaving said first conductive material only in said first opening.

14. The method of fabricating a semiconductor device according to claim 13, wherein
said first barrier film contains a metal including at least one element selected from a group consisting of Ir, Pt, Ru, Re, Ni, Co and Mo, silicon and nitrogen.

15. The method of fabricating a semiconductor device according to claim 14, wherein
said first barrier film includes either an IrSiN film or a PtSiN film.

16. The method of fabricating a semiconductor device according to claim 13, wherein
said first conductive material includes a tungsten plug.
